(19) United States
(12) Patent Application Publication
(10) Pub. No.: US 2008/0122551 A1
(43) Pub. Date: May 29, 2008

(54) APPARATUS FOR PULSE WIDTH MODULATION AND METHOD FOR CONTROLLING THEREOF

(75) Inventors: Li-Min Lee, Taipei City (TW); Chung-Che Yu, Taipei City (TW); Chih-Shun Lee, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: BEYOND INNOVATION TECHNOLOGY CO., LTD., Taipei City (TW)

(21) Appl. No.: 11/609,908

(22) Filed: Dec. 13, 2006

(30) Foreign Application Priority Data
Sep. 11, 2006 (TW) 95133411

(51) Int. Cl. H03K 7/08

(52) U.S. Cl. 332/109

(57) ABSTRACT

An apparatus for generating a pulse width modulated (PWM) signal to control a transforming circuit to drive a loading is provided. The apparatus includes an error signal generator, a control circuit and a comparator. The error signal generator includes a first input terminal for receiving a reference voltage, a second input terminal for receiving a feedback signal generated based on an operating state of the loading respectively, and an output terminal for outputting an error status signal. The comparator includes a first input terminal for receiving the error status signal, a second input terminal for receiving a compare signal, and an output terminal for generating the PWM signal. The control circuit determines whether to provide a setting signal coupled to the output terminal of the error signal generator based on at least one control signal.

### CROSS-REFERENCE TO RELATED APPLICATION

This application claims the priority benefit of Taiwan application serial no. 95133411, filed on Sep. 11, 2006. All disclosure of the Taiwan application is incorporated herein by reference.

### BACKGROUND OF THE INVENTION

1. Field of the Invention

The present invention relates to an apparatus for pulse width modulation (PWM) and a method for controlling the same, and more particularly, to a circuit and a control method capable of lowering the transient period of a PWM apparatus.

2. Description of Related Art

Pulse width modulation (PWM) is a common and a practical control method. Many types of control devices use PWM to drive a loading. For example, in a cold cathode fluorescent lamp (or a light-emitting diode) module, PWM techniques are deployed to control the brightness of the cold cathode fluorescent lamp (or the light-emitting diode).

FIG. 1 is a diagram of a circuit showing the connections between a conventional pulse width modulated apparatus and a loading. As shown in FIG. 1, the conventional pulse width modulated apparatus 100 generates a pulse width modulated signal Sp for controlling the switches (not shown) inside a power transforming apparatus 124 to switch the power transforming apparatus 124. Therefore, external power is transformed to the required electrical power for driving the loading 126. Furthermore, through the feedback circuit 128, a feedback signal Sf is generated to adjust the duty cycle of the pulse width modulated signal Sp.

The conventional PWM apparatus 100 includes an error amplifier 102, a comparator 104, a signal generator 106 and a driving circuit 108. The positive input terminal of the error amplifier 102 receives a reference voltage Vref. The negative input terminal of the error amplifier 102 receives the feedback signal Sf and is coupled to the output terminal of the error amplifier 102 through a compensating capacitor C1. In addition, the negative input terminal of the comparator 104 is coupled to the signal generator 106, and the positive input terminal of the comparator 104 is coupled to the output terminal of the error amplifier 102. The output from the output terminal of the comparator 104 is transmitted to the driving circuit 108.

As shown in FIG. 1, the error amplifier 102 receives the feedback signal Sf and the reference voltage Vref and produces a computational result Sel accordingly. The computational result Sel is sent to the positive input terminal of the comparator 104. On receiving the output from the error amplifier 102, the comparator 104 compares the computational result Sel with a triangular signal Sc generated by the signal generator 106. The result of the comparison is used to control the driving circuit 108 to generate the pulse width modulated signal Sp.

FIG. 2A is a diagram showing the signal waveform of a conventional PWM apparatus from the moment it is enabled to its eventual stabilization. As shown in FIGS. 1 and 2A, the PWM apparatus 100 is assumed to be enabled at time T0. Because the error state signal Se1 is still below the level VL of the signal Sc between time T0 and time T1, the comparator 104 produces no pulse width modulated signal and the loading 126 is not driven. Hence, the feedback signal Sf is 0 (or below 0). Starting at time T1, the output Sel of the error amplifier 102 slowly rises with time due to the charging of the compensating capacitor C1. When the level of the output Sel of the error amplifier 102 reaches the level VL of the signal Sc (at time T2), the driving circuit 108 begins to output the pulse width modulated signal Sp to control the switches of the power transforming apparatus 124. The pulse width modulated signal Sp will settle to a stable state after a period.

As shown in FIG. 2A, the transient period from the enabling of the conventional PWM apparatus 100 to the settling down to a stable operation is relatively long. If the loading 126 operates in a high operating speed system, the entire PWM apparatus 100 may produce some error operations.

Moreover, in the process of dimming the cold cathode fluorescent lamp, the increase in the pulse width of the pulse width modulated signal Sp may lead to an increase in the lamp voltage V_{Lamp} until the lamp is ignited. After the lamp conducts and normal operating voltage is reached for a period of time, the lamp current I_{Lamp} will reach 90% of the predetermined current value. However, due to the characteristic of the lamp as shown in FIG. 2B, a small amount of lamp current I_{Lamp} (the so-called ‘nipple’ current) will appear in the interval from the appearance of the pulse width modulated signal Sp to the lamp voltage reaching the operating voltage. This duration of this ‘nipple’ current and the length of time before the lamp current settling to a stable operating state will affect the correctness of the dimming control or even affect the life span of the lamp. Moreover, the seriousness of this phenomenon is intensified when the length of the lamp tube is increased. Therefore, it is essential to reduce the transient period Tₜₛ from the first appearance of the ‘nipple’ current to the lamp current reaching 90% of the predetermined value.

### SUMMARY OF THE INVENTION

Accordingly, the present invention is to provide a pulse width modulated (PWM) apparatus having a shorter transient period so that the PWM apparatus can be applied to a high speed loading system with the possibility of extending the life span of the loading.

The present invention is also to provide a control circuit and a method for controlling a PWM apparatus to generate a pulse width modulated signal to drive a loading and simultaneously decrease the transient period of the PWM apparatus.

The present invention provides a pulse width modulated (PWM) apparatus for generating a pulse width modulated signal to control a transforming circuit to drive a loading. The apparatus includes an error signal generator, a control circuit and a comparator. The error signal generator includes a first input terminal for receiving a reference voltage, a second input terminal for receiving a feedback signal generated based on an operating state of the loading respectively, and a first output terminal for outputting an error state signal. The comparator includes a third input terminal for receiving the error state signal, a fourth input terminal for receiving a compare signal, and an second output terminal for generating the PWM signal. The control circuit determines whether to provide a setting signal coupled to the first output terminal of the error signal generator based on at least one control signal.

According to another aspect of the present invention, a control circuit suitable for controlling a PWM apparatus is provided. The PWM apparatus includes an error signal generator and a feedback compensation unit. A first input terminal of the error signal generator is coupled to a first reference voltage, a second input terminal is coupled to a feedback signal and an output terminal outputs an error state signal. The feedback compensation unit is coupled between the second input terminal and the output terminal of the error signal generator. The control circuit includes a signal generator coupled to one end of the feedback compensation unit for generating a signal for adjusting the voltage across the feedback compensation unit.

According to another aspect of the present invention, a method for controlling pulse width modulation (PWM) suitable for controlling a PWM apparatus to generate a pulse width modulated signal to control a transforming circuit to drive a loading is provided. The control method in the present invention includes the following steps. First, the state of the PWM apparatus is detected to determine whether or not it is in a specified state or not. When the PWM apparatus is in the specified state, one of the error state signals of the PWM apparatus is set to a predetermined value.

Because the present invention is able to determine whether to set the level of the error state signal to a predetermined value according to the operating state of the PWM apparatus, the transient period of the PWM apparatus can be effectively reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a diagram of a circuit showing the connections between a conventional pulse width modulated apparatus and a loading.

FIG. 2A is a diagram showing the signal waveform of a conventional PWM apparatus from the moment it is enabled to its eventual stabilization.

FIG. 2B is a diagram showing the signal waveform of a conventional PWM apparatus from the moment it is enabled to the eventual stabilization of the lamp current.

FIG. 3 is a diagram of a circuit of a PWM apparatus according to one preferred embodiment of the present invention.

FIG. 4 is a diagram showing the signal waveform of a PWM apparatus from the moment it is enabled to its eventual stabilization.

FIG. 5 is a diagram of a circuit of a PWM-apparatus according to another preferred embodiment of the present invention.

FIG. 6 is a diagram of a control circuit according to one preferred embodiment of the present invention.

FIG. 7 is a block diagram showing the logic components of a switching control circuit according to one preferred embodiment of the present invention.

FIGS. 8A and 8B are diagrams showing the mechanisms for determining a dimming signal and an enabling signal according to one preferred embodiment of the present invention.

FIG. 9 is a block diagram showing the logic components of a switching control circuit according to another preferred embodiment of the present invention.

FIG. 10 is a flow diagram showing a method for controlling a PWM apparatus according to one preferred embodiment of the present invention.

FIG. 11 is a diagram showing the timing and level relationships between various signals when an additional setting signal is provided within a delay period according to the present invention.

FIG. 12 is a diagram of a circuit for providing an additional setting within a delay period.

FIGS. 13A and 13B are diagrams of circuits of a PWM apparatus according to another embodiment of the present invention.

FIG. 14 is a diagram of the timing and level relationships between various signals in the circuit shown in FIG. 13A.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

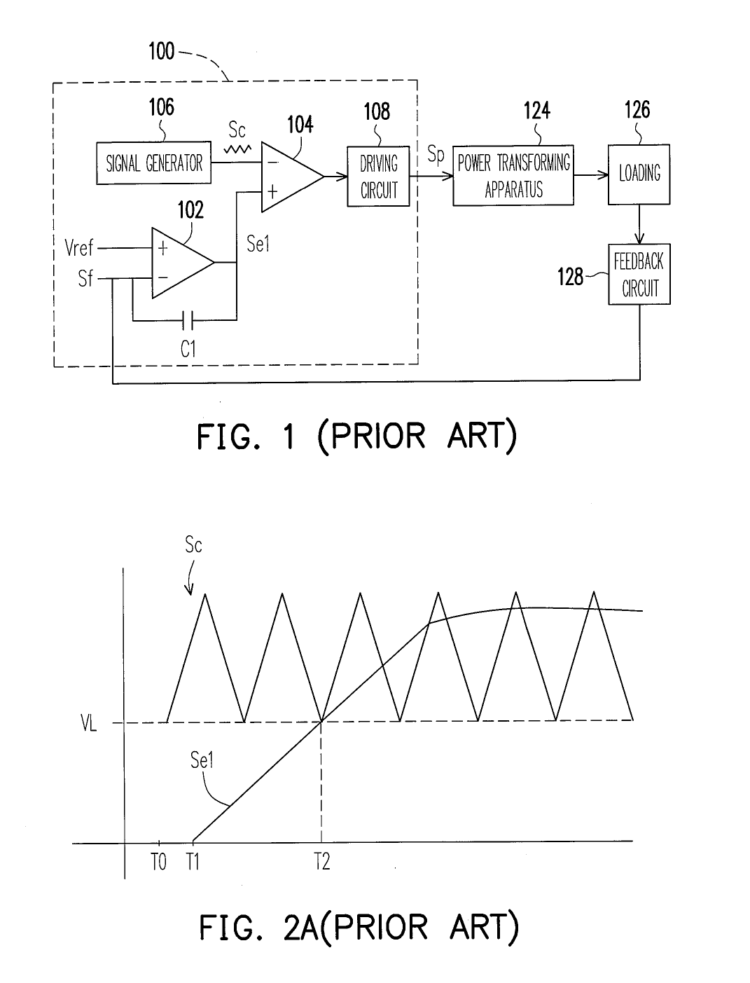

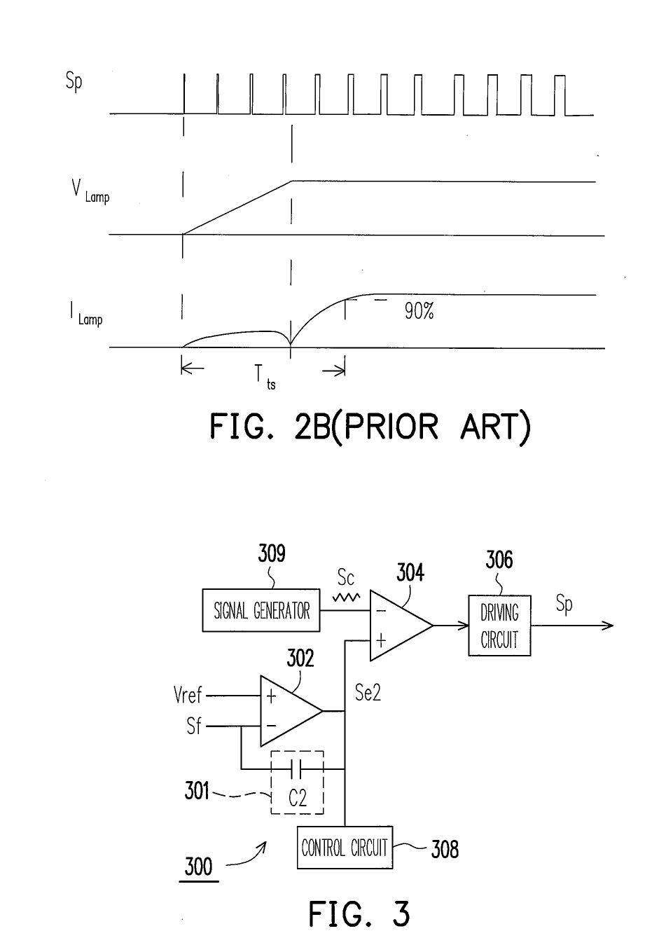

The present invention adjusts the level of the error state signal Se1 through a signal so that the level at the beginning of the operation is already at an appropriate level, thereby shortening time lag between T1 and T2. As shown in FIG. 1, the level of the error state signal Se1 is determined by the level of the feedback signal Sf and the voltage across the compensation capacitor C1. Therefore, the level of the error state signal Se1 can be determined by adjusting the voltage across compensation capacitor C1.

FIG. 3 is a diagram of a circuit of a PWM apparatus according to one preferred embodiment of the present invention. As shown in FIG. 3, the pulse width modulated apparatus 300 of the present invention is able to generate a pulse width modulated signal Sp to control a transforming circuit to drive a loading (not shown). The loading can be a light-emitting diode module or a fluorescent lamp, and the transforming circuit can be a DC-to-DC converter or a DC-to-AC inverter. The PWM apparatus 300 in the present embodiment includes an error signal generator 302, a comparator 304, a driving circuit 306 and a control circuit 308. The driving circuit 306 is a non-essential device, for example, used for driving the NMOS switch of the boost DC-to-DC converter so that the signal from the comparator 304 can directly couple to the control terminal of the NMOS switch. A positive input terminal of the errors signal generator 302 receives a reference voltage Vref. A negative input terminal of the error signal generator 302 receives a feedback signal Sf generated according to the operating condition of the loading, and is coupled to the output terminal of the errors signal generator 302 through a feedback compensation unit 301. The feedback compensation unit 301 in the present embodiment has at least one capacitor C2. In general, the feedback signal Sf can be a current signal or a voltage signal. In the present embodiment, the feedback signal Sf is a voltage. However, no particular restrictions are imposed in the present invention.

In addition, a positive input terminal of the comparator 304 receives an error state signal Se2 output from the error signal generator 302, a negative input terminal of the comparator 304 receives a compare signal Sc, and an output terminal of the comparator 304 is coupled to the driving circuit 306. In the present embodiment, the compare signal Sc can be a triangular wave signal or a saw-tooth wave signal from a signal generator 309.

Also, as shown in FIG. 3, after the error signal generator 302 has received the feedback signal Sf and the reference voltage Vref, the error signal generator 302 generates accordingly the error state signal Se2 to the comparator 304. The comparator 304 compares the error state signal Se2 with the compare signal Sc and generates an output signal (not shown) accordingly. According to the output signal of the comparator 304, the driving circuit 306 generates a pulse width modulated signal Sp.

More specifically, the PWM apparatus 300 in the present embodiment includes a control circuit 308 used for determining whether to adjust the level of the error state signal Se2 according to at least one control signal, and preferably setting the level of the error state signal Se2 to a predetermined value. In the present embodiment, the predetermined value is a predetermined voltage greater than 0 so that the transient period of the PWM apparatus 300 can be reduced.

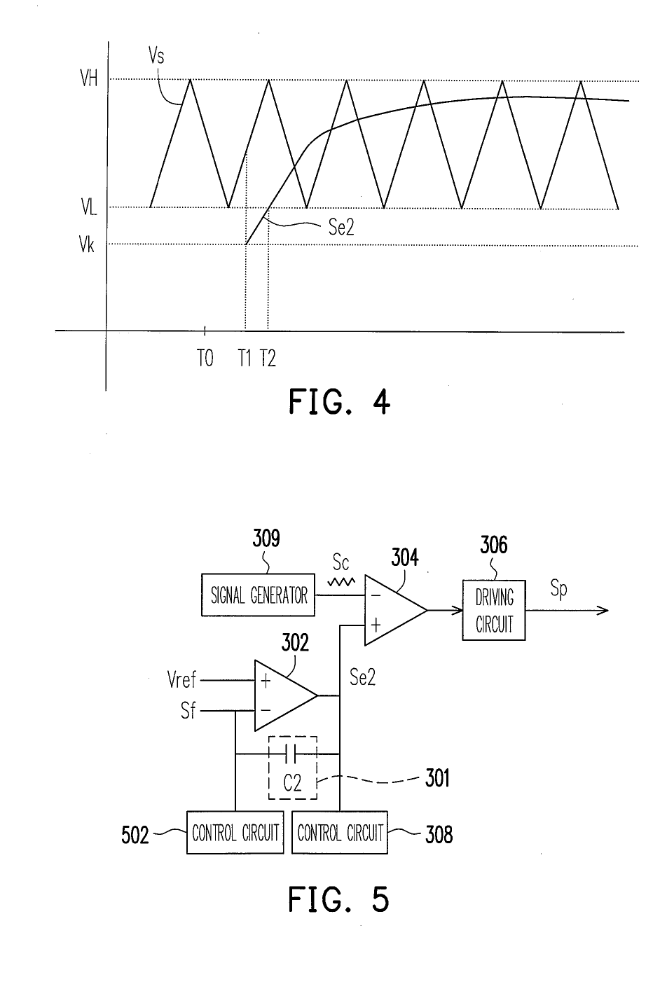

FIG. 4 is a diagram showing the signal waveform of a PWM apparatus from the moment it is enabled to its eventual stabilization. As shown in FIGS. 3 and 4, the control circuit 308 will set the level of the error state signal Se2 to the predetermined voltage value under certain states.

FIG. 4 shows an example of the waveform of the error state signal in the initial state of the PWM apparatus 300. The compare signal Sc can be a triangular wave signal having a first level (peak) VH and a second level (trough) VL. Assume that the PWM apparatus 300 is enabled at time T0. At time T1, the control circuit 308 will set the level of the error state signal Se2 to a predetermined value so that when the PWM apparatus 300 has been enabled and enter a normal operating state, the error state signal Se2 begins at an initial level close to the second level VL. Preferably, the initial level is a predetermined voltage level Vk lower than the second level VL. Thus, within a relatively short period (between T1 and T2), the level of the error state signal Se2 reaches the second level VL to generate the pulse width modulated signal Sp.

For example, in the burst dimming process of the conventional technique, the burst-dimming signal will be transmitted to the negative input terminal of the error signal generator 302. When the burst-dimming signal is at a high voltage level, the transmission of energy to the loading is stopped. Conversely, when the burst-dimming signal is at a low voltage level, the transmission of energy to the loading is resumed. When the burst-dimming signal is at a high voltage level (for example, 3.3 V), the voltage level at the negative input terminal of the error signal generator 302 is pulled up (assuming up to 2.0V) so that the error state signal Se2 from the output of the error signal generator 302 is zero and the voltage across the feedback compensation unit 301 is 2.0V. When the burst-dimming signal is changed to a low voltage of 0V, the feedback signal Sf is also at 0V so that the voltage level at the negative input terminal of the error signal generator 302 is 0V (here, the ground is assumed to be 0V, the same in the following embodiments), and the voltage of the error state signal Se2 at the output terminal of the error signal generator 302 is −2V due to the voltage across the feedback compensation unit 301. Hence, the transient period from −2V to the voltage level VL (assuming to be 0.5V) of the compare signal Sc is relatively long. In the present invention, the error state signal Se2 at the output terminal of the error signal generator 302 is set to 2.4V when the burst-dimming signal is at a high voltage level, so that there is a voltage of −0.4V across the feedback compensation unit 301. Therefore, when the burst-dimming signal is changed to a low voltage of 0V, the error state signal Se2 at the output terminal of the error signal generator 302 is 0.4V. Obviously, for a condition that the voltage level at the negative input terminal of the error signal generator 302 is pulled to the reference voltage Vref, the voltage across the feedback compensation unit 301 can be set in the neighborhood of (VL-Vref). Using Vref=1.0V as an example, when the burst-dimming signal is changed to a high voltage level, the error state signal Se2 can be set to 1.4V so that the voltage across the feedback compensation unit 301 is −0.6V (in the neighborhood of 0.5V-1.0V). Therefore, when the burst-dimming signal is changed to a low voltage level, the voltage level at the negative input terminal of the error signal generator 302 can rapidly reach 1V while the error state signal Se2 begins from 0.4V. For a dimming method that does not send the burst-dimming signal to the negative input terminal of the error signal generator (for example: in the following embodiment, a dimming signal serves as the enable signal EA to enable the PWM apparatus 300, so that when the burst-dimming signal is at a ‘low’ voltage level, the transmission of energy to the loading is stopped, and when the burst-dimming signal is at a ‘high’ voltage level, the transmission of energy to the loading is resumed), person having ordinary skill in the art may deduce on their own the required predetermined value of the voltage across the feedback compensation unit 301. Thus, a detailed description is omitted.

FIG. 5 is a diagram of another preferred embodiment of the PWM apparatus according to the present invention. The components in FIG. 5 that are identical to the ones in FIG. 3 are labeled identically. As shown in FIG. 5, in some selected embodiments, an additional control circuit 502 is disposed on the negative input terminal of the error signal generator 302. By simultaneously disposing the control circuits 308 and 502 at the two terminals of the capacitor C2 of the feedback compensation unit 301, the problem of a possible setting failure, e.g.: only one control circuit sets the level at one terminal of the feedback compensation unit 301 and the other terminal is floating, can be avoided. In other words, if the other terminal is in a floating state during the level setting process, no current flows into the capacitor C2 so that the voltage across the capacitor has no actual change. In one preferred embodiment, the control circuit 502 and the control circuit 308 can have an identical structure. The structure is explained in more detail in the following.

When the voltage level at the output terminal of the error signal generator 302 is set by the control circuit 308 to be the predetermined voltage value, the voltage at the other terminal of the capacitor C2 will not change instantaneously due to voltage continuities in capacitors. To prevent the occurrence of false actions, the control circuit 502, which is able to work synchronously with the control circuit 308, is disposed in the circuit shown in FIG. 5. When the control circuit 308 sets the voltage level at the output terminal of the error signal generator 302 to the predetermined voltage value, the control circuit 502 can simultaneously set the voltage level at the negative input terminal of the error signal generator 302. Preferably, the voltage level at the negative input terminal of the error signal generator 302 is set in the neighborhood of the reference voltage Vref, ideally slightly greater than the reference voltage Vref. Using the foregoing example as one example, the control circuit 502 may set the voltage level at the negative input terminal of the error signal generator 302 to a value slightly greater than 1.0V (=Vref), and the control circuit 308 sets the voltage level at the input terminal of the error signal generator 302 to a value of about 0.4V (˜VL) so that the voltage across the capacitor C2 is in the neighborhood of (VL-Vref).

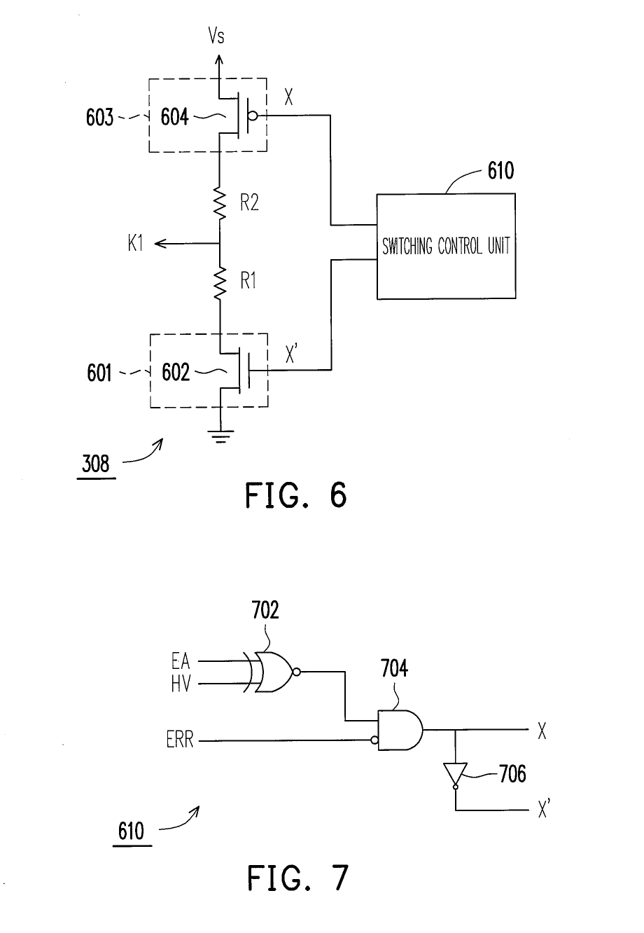

FIG. 6 is a diagram of a control circuit of one preferred embodiment according to the present invention. As shown in FIG. 6, the control circuit 308 in the present embodiment includes a signal generator and a switching control unit 610. The signal generator includes a switch 601 and a switch 603. A first terminal of the switch 601 is grounded and a second terminal is coupled to an output terminal K1 of the control circuit 308 through a resistor R1. A control terminal of the switch 601 is coupled to the switching control unit 610 for receiving a switching signal X′. Furthermore, a first terminal of the switch 603 is coupled to the output terminal K1 of the control circuit 308 through a resistor R2 and a second terminal is coupled to a power source Vs. A control terminal of the switch 603 is coupled to the switching control unit 610 for receiving a switching signal X. In the present embodiment, the switching signals X and X′ are complementary signals.

In the present embodiment, the switch 601 may include an NMOS transistor 602. The first source/drain terminal and the second source/drain terminal of the NMOS transistor 602 are coupled to the first and the second terminal of the switch 601 respectively, and the gate of the NMOS transistor 602 is coupled to the control terminal of the switch 601. Furthermore, the switch 603 may be implemented using a PMOS transistor 604. The first source/drain terminal and the second source/drain terminal of the PMOS transistor 604 are coupled to the first and the second terminal of the switch 603 respectively, and the gate of the PMOS transistor 604 is coupled to the control terminal of the switch 603.

The foregoing description has disclosed the circuit structure of the control circuit 308, and the control circuit 502 in FIG. 5 can be implemented using a structure similar to that of the control circuit 308. Those skilled in the art can easily deduce on their own the structure of the control circuit 502, which is construed to be within the scope of the present invention.

When the switching signal X is at a low voltage level, the switching signal X′ is at a high voltage level so that both transistors 602 and 604 simultaneously conduct. Thus, the resistors R1 and R2 together form a voltage divider circuit and output a voltage signal at the output terminal K1. Therefore, by adjusting the values of the resistors R1 and R2, the level of the error state signal Se2 in FIG. 3 can be set to the desired predetermined value.

FIG. 7 is a block diagram showing the logic components of a switching control circuit according to one preferred embodiment of the present invention. As shown in FIG. 7, the switching control unit 610 in the present embodiment includes an exclusive NOR gate 702, an AND gate 704 and an inverter 706. The exclusive NOR gate 702 receives an enable control signal EA and a working voltage detection signal HV and transmits an output signal to the AND gate 704. In addition to receiving the output from the exclusive NOR gate 702, the AND gate 704 also receives an inverted error detection signal ERR. Furthermore, the output terminal of the AND gate 704 outputs the switching signal X and outputs the switching signal X′ through the inverter 706.

In the present embodiment, the enable control signal EA is used for determining whether to enable the PWM apparatus 300 (as shown in FIG. 3) or not. To enable the PWM apparatus 300, the value of the enable control signal EA is a ‘1’. The working voltage detection signal HV is used for indicating whether the voltage level of the working voltage of the PWM apparatus 300 has reached a working level or not. When the voltage level of the working voltage has reached the working level, the value of the working voltage detection signal HV is ‘1’. In addition, the error detection signal ERR is used for detecting whether the loading operates normally or not. When the loading is not working normally, the value of the error detection signal ERR is ‘1’. In the following, the truth table of the three aforementioned signals of the present invention is shown.

TABLE 1

| States | EA | HV | ERR | X |
|---|---|---|---|---|
| Enabled | 1 | 0 | 0 | 0 |
| Normal | 1 | 1 | 0 | 1 |
| Shut Down | 0 | 1 | 0 | 0 |
| Error | 1 | 1 | 1 | 0 |

As shown in FIGS. 3, 6 and 7 and according to Table 1, when the PWM apparatus 300 of the present invention is first enabled, the enable control signal EA is ‘1’. At this early moment, the working voltage required by the system has still not reached the working level. Therefore, the working voltage detection signal is ‘0’. Because the output from the exclusive NOR gate 702 is ‘0’, the output from the AND gate 704 is also ‘0’ leading to the switching signal X at a low level and the switching signal X′ at a high level so that both transistors 602 and 604 conduct. Thus, the control circuit 308 sets the level of the error state signal to the predetermined value when the PWM apparatus 300 is just enabled.

When the enable control signal EA changes from ‘1’ to ‘0’, the PWM apparatus 300 shut down. If the PWM apparatus only temporarily shut down, the power of the supply system will be maintained above the working voltage level so that the working voltage detection signal is ‘1’ and the output from the exclusive NOR gate 702 is ‘0’. Those skilled in the art would understand that the output from the AND gate 704 is ‘0’. In other words, the switching signal X is ‘0’ and the switching signal X′ is ‘1’ so that both the transistors 602 and 604 conduct. Then, the control circuit 308 forces the level of the error state signal Se2 to the predetermined value. Any output from the PWM apparatus 300 is immediately stopped so that an instantaneous shutdown is achieved. On the other hand, when the PWM apparatus 300 only temporarily shuts down, the level of the error state signal Se2 (as shown in FIG. 4) will not drop to ‘0’ but maintained at the predetermined value. Consequently, the PWM apparatus 300 is able to spend less time to carry out the next enabling operation.

When the operation of the PWM apparatus 300 of the present invention is in error, the error detection signal ERR is ‘1’, and is ‘0’ after an inversion. Therefore, the output from the AND gate 704 is ‘0’ so that the switching signal X is ‘0’ and the switching signal X′ is ‘1’, and both transistors 602 and 604 conduct. Consequently, when the PWM apparatus detects that the loading operates abnormally, the control circuit 308 is able to set the level of the error state signal Se2 to below the lowest level (as shown in FIG. 4) of the compare signal Sc, thereby stopping the generation of the pulse width modulated signal and preventing any erroneous action happening to the loading.

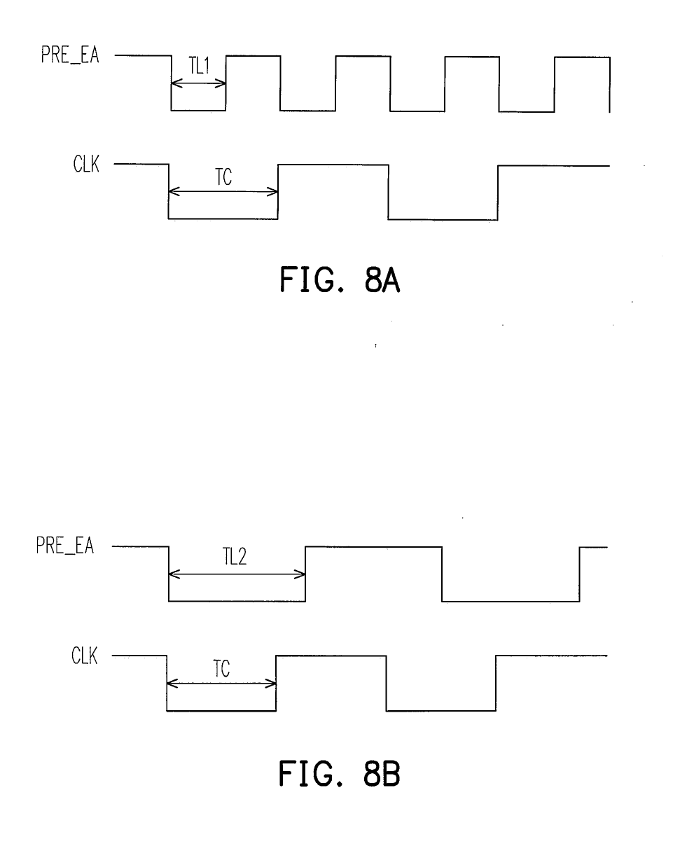

In some embodiments, when the loading is a light source module, for example, a light-emitting diode module, the enable signal EA can also serve as a dimming signal for dimming the loading. FIGS. 8A and 8B are diagrams showing the mechanisms for determining a dimming signal and an enabling signal according to one preferred embodiment of the present invention. The frequency of the dimming signal is generally higher than a predetermined frequency, such as 200 Hz. Hence, the present invention can utilize this characteristic to determine whether the enable signal EA is also used as a dimming signal or not.

As shown in FIGS. 7 and 8A, when the enable control signal PRE_EA is ‘0’ (a low level), the present invention can perform a comparison between the duration TL1 at ‘0’ of the signal PRE_EA and the duration TC of a clock signal CLK. If the duration TL1 that the enable control signal EA is ‘0’ is shorter than the duration TC generated by the predetermined clock signal CLK, the enable signal EA is judged for a dimming operation. Therefore, the state of the receiving terminal of the exclusive NOR gate 702 for receiving the enable signal EA can be set and maintained at ‘1’.

As shown in FIGS. 7 and 8B, if the duration TL2 that the enable control signal EA is ‘0’ is longer than the duration TC generated by the predetermined clock signal CLK, the PWM apparatus is judged to be in a shutdown state. Therefore, the state at the receiving terminal of the exclusive NOR gate 702 for receiving the enable signal EA can be set to ‘0’. Consequently, the enable control signal EA will not be regarded as serving as a dimming signal and hence will not lead to the performance erroneous actions by the system.

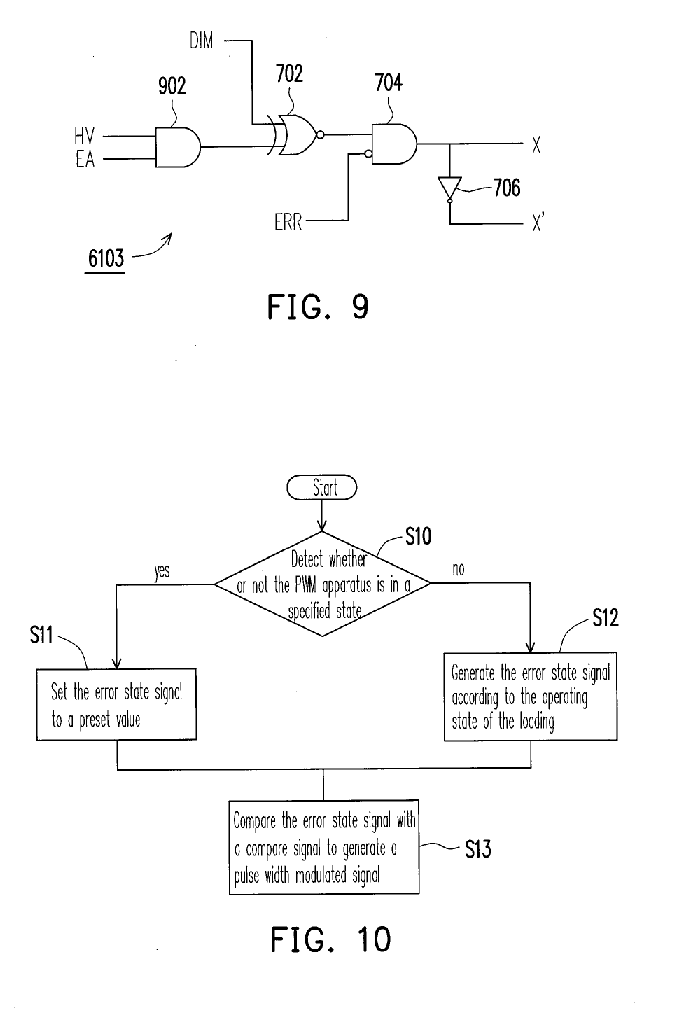

In some other embodiments, the enable control signal EA and the dimming signal are not the same signal. Therefore, FIG. 9 shows another embodiment of the switching control unit. As shown in FIG. 9, the devices identical to the ones shown in FIG. 7 are labeled identically. The switching control unit 6103 includes an AND gate 902, an AND gate 704 and an exclusive NOR gate 702. The AND gate 902 receives the working voltage detection signal HV and the enable control signal EA. The exclusive NOR gate 702 receives the dimming signal DIM and the output from the AND gate 902.

The AND gate 902 receives the working voltage detection signal HV and the enable control signal EA, and generates an output signal accordingly to the exclusive NOR gate 702. The reception of the dimming signal DIM by the AND gate 902 can also be judged by using the steps as shown in FIGS. 8A and 8B. Hence, the occurrence of system malfunction due to misjudgment when the PWM apparatus only temporarily shutdowns can be avoided.

A full description on the operation of the rest of the logic gates in the embodiment shown in FIG. 9 may be referred to FIG. 7. Because those skilled in the art may easily deduce such operations, a detailed description thereof is omitted.

As shown in FIG. 10, the present invention also provides a method for controlling a PWM apparatus. The method for controlling the PWM apparatus in the present embodiment can be applied to the foregoing PWM apparatus 300 for driving a loading. The control method includes the following steps. First, in step S10, whether the PWM apparatus 300 is in a specified state or not is determined according to an operating signal. The specified state can be an initial state, a shutdown state or an error state.

When the state of the PWM apparatus 300 is a specified state, step S11 is executed to set an error state signal of the PWM apparatus 300 to a predetermined value, preferably greater than 0V. Conversely, if the state of the PWM apparatus 300 is not a specified state, step S12 is executed to generate an error state signal according to the operating state of the loading.

Next, in step S13, the error state signal is compared with a compare signal to generate a pulse width modulated signal to drive the loading. The compare signal includes a first level and a second level, wherein the first level is higher than the second level and the second level is higher than the predetermined value. Moreover, in the present embodiment, when the state of the PWM apparatus 300 is not a specified state, the error state signal is generated through comparing a working voltage signal from the loading with a reference voltage.

Because the present invention is capable of setting the level of the error state signal to the predetermined voltage level when the PWM apparatus is in some specified states, the transient period of the PWM apparatus is effectively reduced.

Furthermore, as mentioned before, for some of the loadings (for example, a fluorescent lamp) having a slow enabling period or a slow generating of the feedback signal. In such cases, beside setting the feedback compensation unit 301 based on the 0V voltage level at the negative input terminal of the error signal generator 302, the signals received by the control circuit 308 (for example, the enable control signal EA, the working voltage detection signal HV, the error detection signal ERR, the dimming signal DIM and so on) may be processed with a time delay (a predetermined time delay). Alternatively, the operation of the control circuit 308 is stopped when the feedback signal Sf (or the voltage level at the output terminal of the error signal generator 302) is greater than a predetermined value. As a result, the control circuit 308 is able to accelerate the stabilization of the voltage level at the output terminal of the error signal generator 302 and reduce the transient period of the pulse width modulated signal Sp from its initiation to its stabilization. In other words, after the pulse width modulated signal Sp is generated, the control circuit in the present invention provides an auxiliary signal. Consequently, the feedback compensation unit 301, besides the current generated by the error signal generator 302, also simultaneously receives an auxiliary signal provided by the control circuit 308 to accelerate the adjustment of the voltage across the feedback compensation unit 301 to a stable state. The auxiliary signal can be a voltage signal or a current signal.

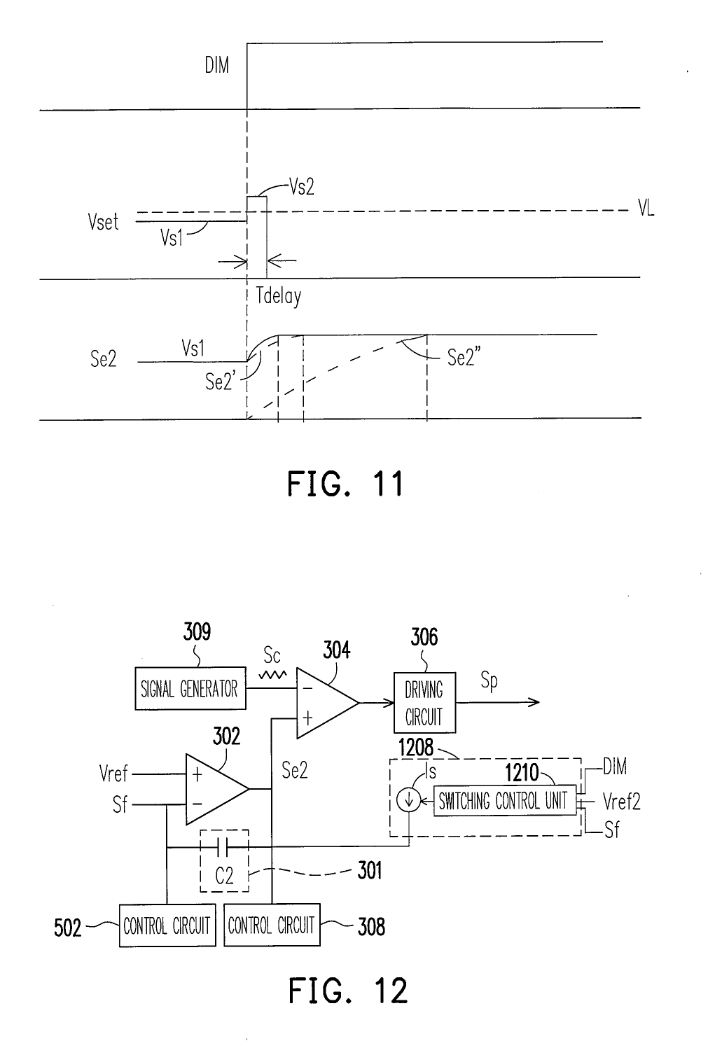

When the auxiliary signal is a voltage signal, the level of the auxiliary signal is preferably higher than the level VL of the compare signal Sc in order to reduce the required transient period of the pulse width modulated signal Sp from its initiation to its stabilization. As shown in FIG. 11, when the dimming signal is at a low level (to stop outputting energy to the loading in the embodiment), the control circuit 308 provides a setting signal Vset whose level is Vs1 (lower than the level VL of the compare signal). When the dimming signal is at a high level (the supply of energy to the loading is resumed in the embodiment), within a delay period Tdelay, a setting signal Vset having a level Vs2 (higher than the level VL of the compare signal) is provided to shorten the required transient period of the pulse width modulated signal Sp from its initiation to its stabilization, for example, the solid line of the signal Se2. Compared with a control circuit 308 without providing a signal (refer to the dash line Se2′) within the delay period Tdelay or the signal Se2 from 0V in the conventional technique (refer to the dash line Se2″), the transient period is shortened considerably. Obviously, if the level Vs1 of the setting signal Vset is higher than the level VL of the compare signal, there is no need to adjust the setting signal Vset to the level Vs2 when the dimming signal is at a high level (the supply of energy to the loading is resumed in the embodiment).

FIG. 12 is a circuit diagram that uses the condition of the feedback signal Sf larger than a predetermined value as the criterion for stopping the output of the control circuit. The auxiliary signal is a current signal and the control circuit 1208 for controlling the auxiliary signal exists as a unit independent of the control circuit 308. The control circuit 1208 comprises a signal generator (a current source Is) and a switching control unit 1210. The switching control unit 1210 receives at least one control signal (for example, the enable control signal EA, the working voltage detection signal HV, the error detection signal ERR, the dimming signal DIM, but the dimming signal DIM is used in the present embodiment). When the dimming signal DIM changes from a low level to a high level, the current source Is is controlled to provide a current signal to the output terminal of the error signal generator 302. When the feedback signal Sf is greater than a reference voltage Vref2 (indicating that the loading starts to conduct), the current from the current source Is is stopped. The reference voltage Vref2 may be equal to the reference voltage Vref at the positive input terminal of the error signal generator 302. The preferred design is that the switching control unit 1210 stops and locks up the current from the current source Is when the feedback signal Sf is greater than a reference voltage Vref2. The switching control unit 1210 is reset while the feedback signal Sf returns to 0V (or below the reset voltage value) or the dimming signal DIM changes to a low level.

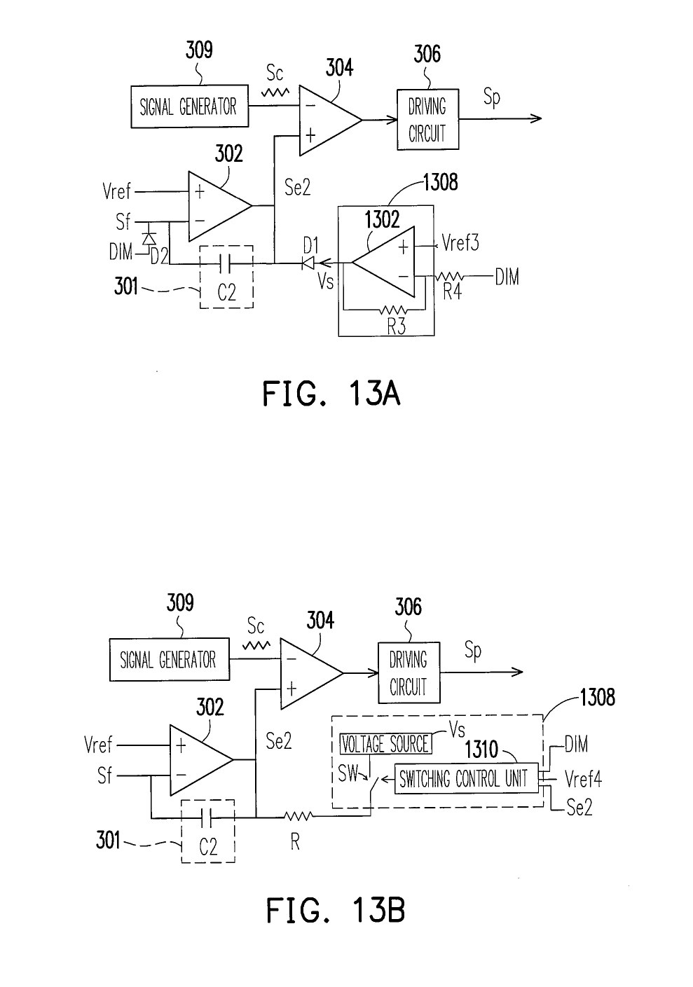

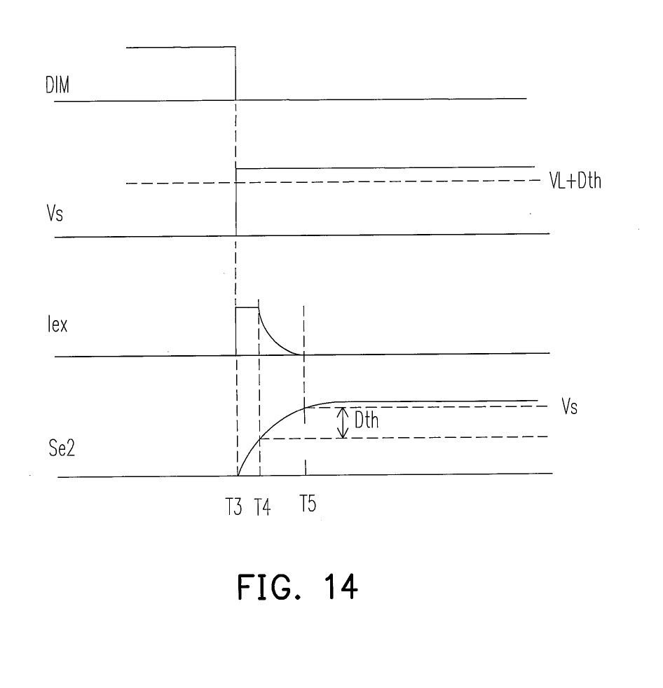

Obviously, the control circuit 1208 for providing the auxiliary signal may exist independently and there is no need to coexist inside the control circuit 308 (and the control circuit 502). FIGS. 13A and 13B are circuit diagrams that use the condition of the voltage level at the output terminal of the error signal generator 302 greater than a predetermined value as the criterion for stopping the output of the auxiliary signal. First, as shown in FIG. 13A, the control circuit 1308 comprises a signal generator. The signal generator is composed of a comparator 1302, a first resistor R3 and a second resistor R4. The comparator 1302 has a negative input terminal, a positive input terminal and an output terminal. The positive input terminal receives a reference voltage signal Vref3. The first resistor R3 is disposed between the negative input terminal and the output terminal of the comparator 1302. One of the terminals of the second resistor R4 is coupled to the negative input terminal of the comparator 1302 and the other terminal receives a control signal (for example, the dimming signal DIM). The output terminal of the control circuit 1308 is coupled to the output terminal of the error signal generator 302 through a rectifying device D1. Because the rectifying device D1 can play the switching role as the switching control unit 1210 in FIG. 12, there is no need to set up a switching control unit inside the control circuit 1308 in FIG. 13A. In the embodiment, when the dimming signal DIM is at a high level, the supply of energy to the loading is stopped. Conversely, when the dimming signal DIM is at a low level, the supply of energy to the loading is resumed. When the dimming signal DIM is at a high level (greater than the reference voltage Vref3), the level of the output voltage Vs of the comparator 1302 is lowered so that the rectifying device D1 is shut off and no current will pass through. Meanwhile, the dimming signal DIM is also coupled to (for example, via a resistor) the negative input terminal of the comparator 302 through a rectifying device D2. When the dimming signal DIM is at a low level, the rectifying device D2 is shut off. Hence, the level of the output voltage Vs of the comparator 1302 rises, preferably to a level higher than the sum of the level VL of the compare signal and the forward bias voltage Dth of the rectifying device D1. As shown in FIG. 14, at time point T3, the control circuit 1308 starts to provide an additional current Iex through the rectifying device D1 to pull up the error state signal Se2 of the error signal generator 302 rapidly. After the time point T4, the voltage difference between the output voltage Vs and the error state signal Se2 is lower than the forward bias voltage Dth of the rectifying device D1. Hence, the additional current Iex drops until the time point T5 (Vs=Se2) is reached. At that point T5, the additional current is zero. Because the additional current Iex changes non-linearly (decreasing rapidly after the time point T4), over-shooting is suppressed.

FIG. 13B is a circuit diagram of a control circuit for providing an auxiliary signal according to another embodiment of the present invention. The control circuit 1308 comprises a switching control unit 1310, a signal generator (that is, a voltage source Vs) and a switch SW. When the dimming signal DIM represents the resumption of outputting energy to the loading, the switching control unit 1310 turns on the switch SW. The voltage source Vs provides a voltage auxiliary signal similar to FIG. 13A and is converted to a current through a passive device (e.g.: a resistor R) for adjusting the voltage across the feedback compensation unit 301. As a result, the level of the error state signal Se2 is raised up rapidly. When the error state signal Se2 reaches the reference voltage Vref4, the switching control unit 1310 turns off (and preferably locks up the turned-off state of) the switch SW. The reference voltage Vref4 is preferably greater than the level VL of the compare signal Sc.

Through the embodiments shown in FIGS. 12, 13A and 13B, the provision of an additional auxiliary signal can effectively shorten the transient period from initiating the transmission of energy to the loading to the stabilization of the current in the loading. In particular, for fluorescent lamps or other loading with a similar driving characteristic, the shortening of the period from the generation of the pulse width modulated signal to the voltage of the lamp reaching the operating voltage can reduce the duration of the lamp current in the ‘nipple’ zone.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A pulse width modulation (PWM) apparatus for generating a pulse width modulated signal to control a transforming circuit to drive a loading, the pulse width modulation apparatus comprising:
an error signal generator, having a first input terminal, a second input terminal and a first output terminal, wherein the first input terminal and the second input terminal are coupled to a first reference voltage and a feedback signal generated based on an operating state of the loading respectively, and the first output terminal outputs an error state signal;
a first comparator, having a third input terminal, a fourth input terminal and a second output terminal, wherein the third input terminal receives the error state signal, the fourth input terminal receives a compare signal, and the second output terminal outputs the pulse width modulated signal; and
a first control circuit, for providing a first setting signal coupling to the first output terminal of the error signal generator based on at least one control signal.

2. The PWM apparatus of claim 1, wherein the compare signal is a triangular wave or a saw-tooth wave and the level of the first setting signal is substantially equal to or below a trough level of the compare signal.

3. The PWM apparatus of claim 1, further comprising a feedback compensation unit, having one terminal coupled to the second input terminal of the error signal generator and another terminal coupled to the first output terminal of the error signal generator.

4. The PWM apparatus of claim 3, wherein the level of the first setting signal is determined based on at least one of the level of the compare signal and the first reference voltage.

5. The PWM apparatus of claim 4, wherein the first setting signal is for adjusting a voltage across the feedback compensation unit

6. The PWM apparatus of claim 1, wherein the first control circuit comprises a first switching control unit for controlling whether or not to output the first setting signal.

7. The PWM apparatus of claim 6, wherein the first control circuit comprises:
a first switch, for determining whether or not to couple the first output terminal of the error signal generator to ground according to a first switching signal generated by the first switching control unit; and
a second switch, for determining whether or not to couple the first output terminal of the error signal generator to a voltage source according to a second switching signal generated by the first switching control unit.

8. The PWM apparatus of claim 7, wherein the first switch is an NMOS transistor with a first source/drain terminal grounded, a second source/drain terminal coupled to the first output terminal of the error signal generator through a first resistor and a gate terminal coupled to the first switching signal, and the second switch is a PMOS transistor with a first source/drain terminal coupled to the first output terminal of the error signal generator through a second resistor, a second source/drain terminal coupled to the voltage source and a gate terminal coupled to the second switching signal.

9. The PWM apparatus of claim 1, wherein the least one control signal comprises an enable control signal, a working voltage detection signal, an error detection signal, a dimming signal, the feedback signal or the error state signal.

10. The PWM apparatus of claim 9, wherein the first control circuit continuously provides the first setting signal for a period after the dimming signal represents to resume a transmission of energy to the loading wherein the period is determined based on the level of the least one control signal.

11. The PWM apparatus of claim 1, further comprising a second control circuit for providing a second setting signal coupled to the second input terminal of the error signal generator based on at least one control signal.

12. The PWM apparatus of claim 11, wherein the second control circuit comprises a second switching control unit for controlling whether or not to output the second setting signal.

13. The PWM apparatus of claim 12, wherein the second control circuit further comprises:
a third switch, for determining whether or not to couple the second input terminal of the error signal generator to ground according to a third switching signal generated by the second switching control unit; and
a fourth switch, for determining whether or not to couple the second input terminal of the error signal generator to a voltage source according to a fourth switching signal generated by the second switching control unit.

14. The PWM apparatus of claim 11, wherein the level of the second setting signal is substantially equal to or above the level of the first reference voltage.

15. The PWM apparatus of claim 1, further comprising a third control circuit for providing an auxiliary signal coupled to the first output terminal of the error signal generator based on at least one control signal.

16. The PWM apparatus of the claim 15, wherein at least one of the control signals comprises a dimming signal, the feedback signal, or the error state signal.

17. The PWM apparatus of claim 16, wherein the third control circuit comprises a current source and a switching control unit, and the switching control unit is used for determining whether or not the current source provides a current signal as the auxiliary signal based on at least one control signal.

18. The PWM apparatus of claim 16, wherein the third control circuit comprises a voltage source, a switch and a switching control unit, the voltage source is coupled to the first output terminal of the error signal generator via the switch, and the switching control unit controls the switch so as to determine whether the voltage source provides a voltage signal as the auxiliary signal based on at least one control signal.

19. The PWM apparatus of claim 16, wherein the third control circuit comprises:
a second comparator, having a fifth input terminal, a sixth input terminal and a third output terminal, and wherein the sixth input terminal of the second comparator is coupled to a second reference voltage;
a first resistor, coupled between the fifth input terminal of the second comparator and the third output terminal of the second comparator; and
a second resistor, having one terminal coupled to the fifth input terminal of the second comparator and another terminal coupled to at least one control signal.

20. The PWM apparatus of claim 19, further comprising a first rectifying device coupled between the third output terminal of the second comparator and the third input terminal of the first comparator.

21. The PWM apparatus of claim 20, wherein the dimming signal is coupled to the second input terminal of the error signal generator through a second rectifying device.

22. The PWM apparatus of claim 18, wherein the auxiliary signal is coupled to the first output terminal of the error signal generator through a passive device.

23. The PWM apparatus of claim 22, wherein the passive device comprises a resistor or a rectifying device.

24. A control circuit suitable for controlling a pulse width modulation (PWM) apparatus, the PWM apparatus comprising an error signal generator and a feedback compensation unit, a first input terminal of the error signal generator coupled to a first reference voltage, a second input terminal coupled to a feedback signal and a first output terminal outputs an error state signal, wherein the feedback compensation unit is coupled between the second input terminal and the first output terminal, the control circuit comprising:
a signal generator, coupled to a terminal of the feedback compensation unit for generating a signal to adjust a voltage across the feedback compensation unit.

25. The control circuit of the claim 24, further comprising a switching control unit, coupled to at least one control signal and controlling the signal generator whether or not to output the signal accordingly.

26. The control circuit of claim 25, wherein the least one control signal comprises an enable control signal, a working voltage detection signal, an error detection signal, a dimming signal, the feedback signal or the error state signal.

27. The control circuit of claim 25, wherein the terminal of the feedback compensation unit is coupled to the first output terminal of the error signal generator.

28. The control circuit of claim 27, wherein the PWM apparatus further comprises a first comparator having a third input terminal, a fourth input terminal and a second output terminal, the third input terminal receives the error state signal, the fourth input terminal receives a compare signal, and the second output terminal outputs a pulse width modulated signal.

29. The control circuit of claim 28, wherein the level of the signal of the signal generator is determined by the level of the compare signal.

30. The control circuit of claim 29, wherein the compare signal is a triangular wave or a saw-tooth wave, and the level of the signal of the signal generator is substantially equal to or below a trough level of the compare signal.

31. The control circuit of claim 25, wherein the terminal of the feedback compensation unit is coupled to the second input terminal of the error signal generator.

32. The control circuit of claim 31, wherein the level of the signal of the signal generator is determined by the first reference voltage.

33. The control circuit of claim 32, wherein the level of the second setting signal is substantially equal to or above the level of the first reference voltage.

34. The control circuit of claim 25, wherein the signal generator comprises:
a first switch, having a first terminal, a second terminal and a first control terminal, wherein the first terminal is grounded, the second terminal is coupled to the terminal of the feedback compensation unit, and the first control terminal is coupled to the switching control unit; and
a second switch, having a third terminal, a fourth terminal and a second control terminal, the third terminal is coupled to the terminal of the feedback compensation unit, the fourth terminal is coupled to a voltage source, and the second control terminal is coupled to the switching control unit.

35. The control circuit of claim 34, wherein the switching control unit comprises:
an exclusive NOR gate, wherein an input terminal thereof receives an enable control signal, another input terminal thereof receives a working voltage detection signal;
an AND gate, wherein one of input terminals thereof receives the output from the exclusive NOR gate, another input terminal thereof receives an inverted error detection signal, and the output terminal of the AND gate provides a second switching signal to the control terminal of the second switch; and
an inverter, for receiving the second switching signal to generate a first switching signal to the control terminal of the first switch.

36. The control circuit of claim 34, wherein the switching control unit comprises:
a first AND gate having a first input terminal, a second input terminal and an output terminal wherein the first input terminal thereof receives a working voltage detection signal of the PWM apparatus, and the second terminal thereof receives the enable control signal;
an exclusive NOR gate, wherein an input terminal thereof receives a dimming signal, another input terminal thereof receives an output signal from the output terminal of the first AND gate;
a second AND gate, wherein an input terminal thereof receives the signal from the output terminal of the exclusive NOR gate, another input terminal thereof receives an inverted error detection signal, and the output terminal of the second AND gate provides a second switching signal to the control terminal of the second switch; and
an inverter, for receiving the second switching signal to generate a first switching signal to the control terminal of the first switch.

37. The control circuit of claim 25, wherein the signal generator comprises a voltage source and a switch, the voltage source is coupled to the terminal of the feedback compensation unit via the switch, and the switching control unit controls the switch so as to determine whether the voltage source provides the signal based on at least one control signal.

38. The control circuit of claim 24, wherein the signal generator comprises:
a second comparator, having a fifth input terminal, a sixth input terminal and a third output terminal, and the sixth input terminal of the second comparator is coupled to a second reference voltage;
a first resistor, coupled between the sixth input terminal of the second comparator and the third output terminal of the second comparator; and
a second resistor, having a terminal coupled to the sixth input terminal of the second comparator, and another terminal coupled to at least one control signal.

39. The control circuit of claim 38, wherein the third output terminal of the second comparator is coupled to the first output terminal of the error signal generator through a passive device.

40. The control circuit of claim 39, wherein the passive device is a first rectifying device.

41. The control circuit of claim 39, wherein the least one control signal comprises a dimming signal.

42. The control circuit of claim 41, wherein the dimming signal is coupled to the second input terminal of the error signal generator through a second rectifying device.

43. A method for controlling pulse width modulation (PWM), suitable for controlling a PWM apparatus to generate a pulse width modulated signal to control a transforming circuit to drive a loading, the control method comprising the steps of:
detecting whether or not the state of the PWM apparatus is in a specified state; and
setting an error state signal of the PWM apparatus to a predetermined value when the state of the PWM apparatus is the specified state.

44. The method of claim 43, wherein the specified state comprises an initial state, a shut down state or an error state.

45. The method of claim 43, further comprising the steps of:
generating the error state signal according to the operating state of the loading when the state of the PWM apparatus is not the specified state; and
comparing the error state signal with a compare signal to generate the pulse width modulated signal, wherein the compare signal has a first level and a second level, and the first level is greater than the second level.

46. The method of claim 45, wherein the predetermined value is a voltage substantially equal to or below the second level.
